(19) United States
(12) Patent Application Publication
(10) Pub. No.: US 2014/0027155 A1
(43) Pub. Date: Jan. 30, 2014

(54) DIFFERENTIAL MODE SIGNAL CONNECTOR AND CABLE ASSEMBLY

(71) Applicants: Daniel Smith, Westerly, RI (US); Christopher Scanlon, Cranston, RI (US); John MacIver, Westerly, RI (US)

(72) Inventors: Daniel Smith, Westerly, RI (US); Christopher Scanlon, Cranston, RI (US); John MacIver, Westerly, RI (US)

(73) Assignee: AMETEK, INC., Berwyn, PA (US)

(21) Appl. No.: 13/557,514

(22) Filed: Jul. 25, 2012

(51) Int. Cl. H01R 24/00; H05K 1/00; H01R 13/52; H01B 11/04; H02G 15/02

(52) U.S. Cl. 174/250; 174/113 R; 174/74 R; 174/77 R; 439/626; 439/271

(57) ABSTRACT

A cable assembly and a connector assembly is disclosed. The cable assembly includes a cable having a connector assembly attached on one end and a plurality of conductor pairs extending through the cable, wherein each conductor in a first conductor pair is equidistant to each conductor in a second conductor pair adjacent to the first conductor pair. The connector assembly includes a housing and a plurality of connector contact pairs extending through the housing, wherein each connector contact is associated with one of the conductors in the cable assembly and each connector contact in a first connector contact pair is equidistant to each connector contact in a second connector contact pair adjacent to the first connector contact pair. The connector assembly may be hermetically sealed.

### FIELD OF THE INVENTION

This invention relates to electrical connectors and cables for signal transmission.

### BACKGROUND OF THE INVENTION

As signal bandwidth demands have increased, the issue of signal cross-contamination, commonly referred to as “crosstalk”, has become ever more challenging. Increasing bandwidth requires a proportional increase in signal frequency, which in turn makes it easier for signal energy to jump the dielectric barrier between adjacent signal transmission lines.

Examples of methods generally employed to prevent external interference of signal transmission include twisted pair cabling and differential mode signal transmission. Twisted pair cabling is a type of wiring in which two conductors of a single circuit are twisted together for the purposes of canceling out electromagnetic interference from external sources. Differential mode signal transmission, or the simultaneous transmission of a signal on one line conductor and an equal and opposite signal on the other, was introduced in twisted pair and parallel conductor transmission applications to provide a simple means of cancelling undesired external noise.

RS-422, USB, and Ethernet protocols, which are common protocols for high-speed signal transmission, all employ differential mode signals. In those protocols where multiple transmission lines are bundled together for collective data transmission, the problem of crosstalk becomes an issue. Because all signals are differential mode, the possibility of the differential signal in one twisted pair inducing differential interference within an adjacent pair is considerable.

Ethernet in particular, which has rapidly progressed from 10 Mbps to 1000 Mbps service bandwidths, has created the need of ever more stringent control of signal contamination between adjacent pairs. Most high-end Ethernet connections employ a registered jack (RJ) connector to minimize crosstalk. However, even with RJ connectors, each connection point creates a means by which crosstalk can occur, the magnitude of which is proportional to the physical and electrical lengths of that connection.

As differential signal connectors have been introduced into military and industrial applications, the demand has increased for specifically designed differential signal connectors to reliably operate in harsh usage environments and conditions, also known as “ruggedized” connectors. As used herein, “ruggedized” means specifically designed to reliably operate in harsh usage environments and conditions, such as strong vibrations, extreme temperatures, wet conditions, and/or dusty conditions. Some designs for such connectors included placing an RJ connector within a larger protective connector, preventing dust and water ingress, but those designs maintained the RJ connector's spring contacts which were not ideal when subjected to mechanical shocks or vibrations. More traditional pin-and-socket connectors, such as M12 style connectors, offer a much more robust, reliable, and compact interface with similar ingress protection. However, the crosstalk introduced by lengthy connections limit performance.

The Telecommunications Industry Association (“TIA”) has set new category protocols increasing the difficulty in the production of a cable and connectors that meets performance demands with respect to crosstalk. The transmission standards for “Category 6” cable has proven elusive for manufacturers of differential signal connectors. Category 6 Ethernet is far less tolerant of crosstalk than the earlier Category 5e, which is necessary for the clear transmission of information at high frequencies in all four data pairs of such connectors operating in full duplex mode.

### SUMMARY OF THE INVENTION

Embodiments of the inventive differential mode signal connectors and cable assemblies described herein overcome the disadvantages of previous differential mode signal connectors and cable assemblies.

In accordance with one embodiment of the invention, there is provided a cable assembly including a cable and a plurality of conductor pairs extending therethrough, wherein each conductor in a first conductor pair is equidistant to each conductor in a second conductor pair adjacent to the first conductor pair. A connector assembly attached to an end of the cable includes a plurality of connector contact pairs extending through the connector, wherein each connector contact is associated with a conductor.

In accordance with another embodiment of the invention, there is provided a connector assembly comprising a housing and a plurality of connector contact pairs extending through said housing, wherein each connector contact in a first connector contact pair is equidistant to each connector contact in a second connector contact pair adjacent to the first connector contact pair. An odd number of connector contact pairs may be present in the connector assembly.

The connector assembly according to one embodiment of the invention is preferably a hermetically sealed connector.

### BRIEF DESCRIPTION OF THE DRAWINGS

Other aspects and advantages of the invention will be apparent from the following detailed description wherein reference is made to the accompanying drawings. In order that the invention may be more fully understood, the following figures are provided by way of illustration, in which:

FIG. 1a is a cross-sectional view of two adjacent conductor pairs according to an embodiment of the present invention;

FIG. 1b is a cross-sectional view of two conductor pairs according to a second embodiment of the present invention;

FIG. 1c is a cross-sectional view of two conductor pairs according to a third embodiment of the present invention;

FIG. 2a is a cross-sectional view of a prior art connector demonstrating a spatial optimum pattern;

FIG. 2b is a cross-sectional view of another prior art connector demonstrating a spatial optimum pattern;

FIG. 3a is a cross-sectional view of a contact pattern according to one embodiment of the present invention;

FIG. 3b is a cross-sectional view of a contact pattern according to another embodiment of the present invention;

FIG. 3c is a cross-sectional view of a contact pattern according to yet another embodiment of the present invention;

FIG. 4a is a cross-sectional view of a first contact pattern tested for Category 6 Near-End Crosstalk;

FIG. 4b is a cross-sectional view of a second contact pattern tested for Category 6 Near-End Crosstalk;

FIG. 4c is a cross-sectional view of a third contact pattern tested for Category 6 compliance;

FIG. 4d is a cross-sectional view of a fourth contact pattern tested for Category 6 compliance;

FIG. 4e is a cross-sectional view of a fifth contact pattern tested for Category 6 compliance;

FIG. 4f is a cross-sectional view of a sixth contact pattern tested for Category 6 compliance;

FIG. 4g is a cross-sectional view of a seventh contact pattern tested for Category 6 compliance;

FIG. 4h is a cross-sectional view of an eighth contact pattern tested for Category 6 compliance;

FIG. 4i is a cross-sectional view of a ninth contact pattern tested for Category 6 compliance;

FIG. 4j is a cross-sectional view of a tenth contact pattern tested for Category 6 compliance;

FIG. 4k is a cross-sectional view of a contact pattern according to an embodiment of the present invention tested for Category 6 compliance; and

FIG. 4l is a cross-sectional view of a contact pattern according to another embodiment of the present invention tested for Category 6 compliance.

### DETAILED DESCRIPTION OF THE INVENTION

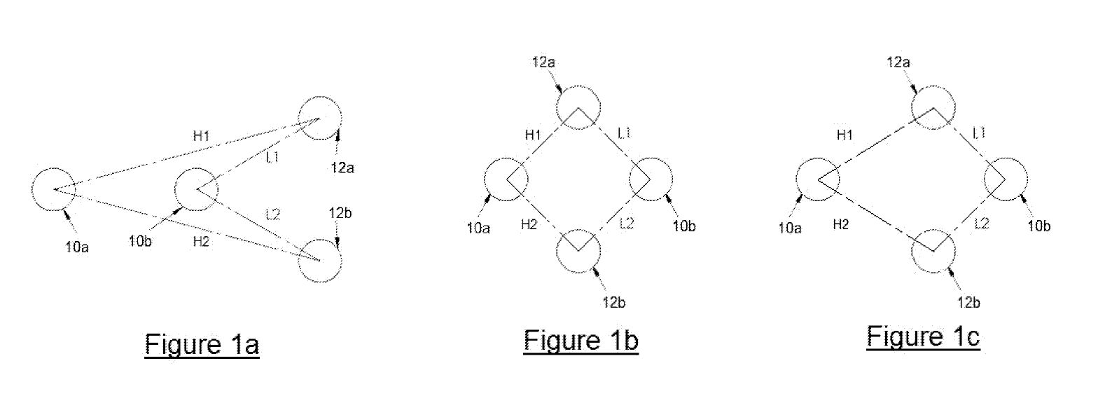

FIG. 1a is a cross-sectional view of four conductors 10a, 10b, 12a, and 12b arranged in a “T” pattern. According to one embodiment of the invention, a first conductor pair 10a, 10b is oriented perpendicular to a second conductor pair 12a, 12b, such that each conductor in the first conductor pair is equidistant to the conductors in the adjacent second conductor pair. As used herein, the term “equidistant” means that each conductor in a first conductor pair is substantially the same distance to each conductor in a second conductor pair. Preferably, the difference between lengths L1 and L2 or H1 and H2 is within 5% of either length and more preferably 2% or less of either length.

In the embodiment illustrated in FIG. 1a, the first conductor 10a in the first conductor pair is located a first distance H1 from a first conductor 12a in the second conductor pair and a second distance H2 from a second conductor 12b in the second conductor pair, wherein the first distance H1 is about equal to the second distance H2. Likewise, the second conductor 10b of the first pair is also equidistant to both conductors 12a, 12b of the second pair, as the distance L1 is about equal to the second distance L2.

FIG. 1b is a cross-sectional view of four conductors 10a, 10b, 12a, and 12b arranged in a “+” pattern. According to an embodiment of the invention, a first conductor pair 10a, 10b and a second conductor pair 12a, 12b are oriented such that the two pairs share a midpoint and each conductor in one pair is equidistant to the conductors in the other pair. Similar to FIG. 1a, the embodiment illustrated in FIG. 1b includes a first conductor 10a in a first conductor pair located a first distance H1 from a first conductor 12a in a second conductor pair and a second distance H2 from a second conductor 12b in the second conductor pair, wherein H1 and H2 are substantially equal. Likewise, the second conductor 10b of the first pair is also equidistant to both conductors 12a, 12b of the second pair. Unlike the embodiment in FIG. 1a, the embodiment illustrated in FIG. 1b results in the conductors of the vertical pair 12a, 12b also being equidistant to each of the conductors in the horizontal pair 10a, 10b because the two conductor pairs share a midpoint; therefore, the distances H1, H2, L1, and L2 are all substantially equal. It is not necessary for the conductor pairs to share a midpoint. For example, in the embodiment illustrated in FIG. 1c, the respective planes through which conductor pairs extend intersect at an approximately right angle, such that the distance between adjacent conductors will equal one adjacent distance, but not both, i.e. for conductor patterns made according to the embodiment of FIG. 1c, H1 can be substantially equal to either H2 or L1, but not both H2 and L1.

By arranging the conductor pairs according to an embodiment of the present invention, crosstalk between adjacent pairs can be resolved to common mode. Thus, crosstalk is prevented by the implementation of a design in which conductor pairs 10, 12 are laid out not in a flat pattern, but in an alternating pattern of horizontally and vertically arranged pairs. The vertical pairs will receive a noise signal from the adjacent horizontal pairs which is purely a common mode signal, and will induce no net signal in those adjacent pairs for the entirety of the length of a cable. Common mode interference is cancelled by differential signal processing architecture and, thus, constitutes no undesired noise. The differential signal transmitted through the second pair of conductors 12a, 12b self-cancels noise induced in the first pair of conductors 10a, 10b, while noise received by the second conductor pair 12a, 12b is resolved to common mode.

When manufacturing cable, parallel conductors make for inexpensive and efficient construction because such cables, such as ribbon cable, can be produced from continuous processes involving well-known fabrication equipment. Wires can be pulled through and the insulation material can then be continuously extruded over them. Twisted pairs, on the other hand, need wires to be constantly wound about each other, and, in multiline cables, pairs need to be further wound about each other in a helical lay. Twisted pairs require more elaborate tooling and are more difficult to build in longer runs. As such, the process of making cables including twisted conductor pairs is ordinarily much more expensive than parallel conductor cable.

The disadvantage associated with parallel conductors, as noted above, is their susceptibility to noise, not only from external sources, but also between adjacent transmission lines. Because each wire of a given pair induces and in turn receives noise from one and only one adjacent unpaired conductor, crosstalk is by nature a differential noise signal, which can degrade the available data transmission bandwidth. However, ribbon cable manufactured in accordance with aspects of the present invention demonstrate acceptable crosstalk levels between adjacent unpaired conductors for differential signal transmission applications, such as Gigabit Ethernet.

The ability to feed high-quality differential signals on parallel conductors allows Ethernet and other data protocols to be implemented more easily and more cost effectively than what has previously been achieved. Less expensive cables and simpler connectors could be developed to take advantage of the conductor or connector pattern made according to an embodiment of the present invention. In addition to cable, layered circuit boards and other transmission lines can take advantage of this conductor geometry. On a layered circuit board, horizontal conductor pairs may be printed on a single layer along a first plane, while each conductor forming a vertical pair and extending in the same direction as the horizontal pair would be printed on separate planes either above or below the plane of the horizontal pairs, such that each conductor in the vertical pair is equidistant to each of the conductors in the horizontal pair and all of the conductors are substantially parallel to each other. The conductors may have any form, so long as the cross-sectional area of the conductors are similar in size and shape.

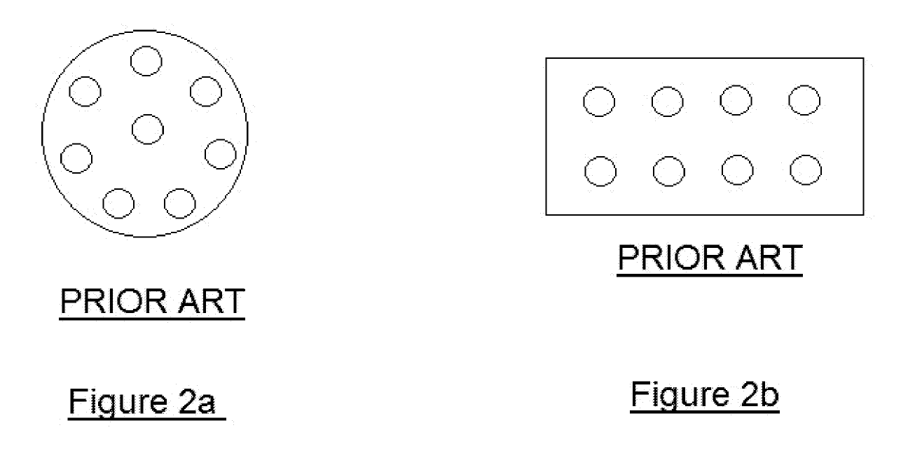

With respect to the connector assembly affixed to the end of the cable, patterns for the connector contacts or “contacts” extending through the body of the connector assembly may be arranged to minimize the overall size of a connector. Crosstalk readings can be affected by connection length, insulation material, contact spacing, wiring arrangement, termination style, and termination quality. However, proximity is the main driver of crosstalk, such that adjacently-wired data pairs will likely have the worst crosstalk performance. Since size and weight can be factors in connector selection, spatially optimized contact patterns are conventionally used, and very little attention has been paid to the impact of contact pattern geometry on crosstalk performance. Examples of spatial optimum patterns for contacts currently used in the art are shown in FIG. 2.

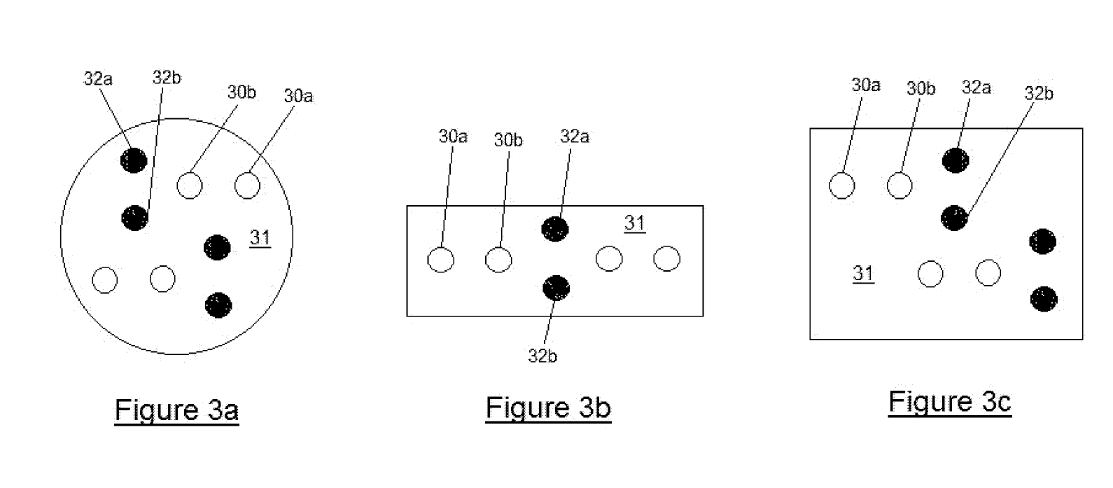

One embodiment of the present invention provides a connector assembly that includes pairs of connector contacts in a “T” pattern, such as the connector “T” pattern described above with respect to FIG. 1a. Embodiments of various patterns are illustrated in FIGS. 3a, 3b, and 3c. In a “T” pattern arrangement, total crosstalk between the pairs is generally zero. Because the contacts of a first pair are aligned with the midpoint between the contacts of a second adjacent pair, the contacts in the first pair is an equal distance to each contact in the adjacent perpendicular pair. The connector contacts are surrounded by an encapsulating material 31. In one embodiment, the encapsulating material 31 is applied, such that the connector contacts are hermetically sealed in the connector. Preferably, the encapsulating material and method of sealing the connector contacts within the encapsulating material is selected, such that the connector is ruggedized. In one embodiment, the encapsulating material is insert molding material, such as plastic, for example. In another embodiment, the encapsulating material may be glass or ceramic. One of ordinary skill in the art would recognize various methods and materials for sealing the connector contacts in the connector according to the aspects of the present invention.

In FIGS. 3a, 3b, and 3c, the crosstalk received by each contact in a first contact pair 30a, 30b is zero as a result of destructive interference. The differential signal in the second contact pair 32a, 32b induces two noise signals of equal magnitude and opposite phase, which in turn sum to zero. Conversely, the crosstalk received by the second contact pair 32a, 32b is resolved to a purely common mode, and thus completely cancelled at the receiver. Each contact 30a, 30b in the first pair can be regarded as a separate source of signal interference. Because each source of interference is equidistant from both contacts of the second contact pair 32a, 32b, the induced noise signal in each contact in the second pair has the same magnitude and phase, which is the definition of common mode. The contact 30b which is closer to the second pair will induce a much greater signal in terms of magnitude, but since both induced signals are common mode, the sum of both signals is also common mode. Thus, providing a connector assembly with a repeating “T” pattern will provide the advantage of improved performance by minimizing crosstalk.

For two-pair differential mode signal transmission, the “T” or “+” pattern arrangement is theoretically perfect for purposes of avoiding crosstalk. When adding additional data pairs beyond two, the challenge becomes more difficult. However, it is still possible, regardless of the number of pairs or the overall shape of the desired connector package, to ensure that all adjacent contact pairs are arranged in a manner which enforces the basic “T” pattern. As illustrated in FIGS. 3a, 3b, and 3c, both circular and rectangular contact arrangements may be made to enforce the required geometric relationships between adjacent data pairs. The number of pairs may be odd (FIG. 3b) or even (FIGS. 3a and 3c). Although three arrangements are depicted, one of ordinary skill in the art will recognize from the description herein that other connector arrangements applying the principles of the present invention will exhibit improved performance and are considered within the scope of the present invention.

Although crosstalk between adjacent pairs within a repeating “T” pattern will be zero, crosstalk between non-adjacent pairs will be non-zero. Since nonadjacent pairs are further separated, and are often buffered by adjacent-pair field effects, the magnitude of this crosstalk is an amount such that these contact patterns might be regarded as an optimal balance of data performance and spatial efficiency. In both instances, additional space may be needed over and above what is needed for a spatially optimized contact configuration.

For example, to accommodate the repeating “T” pattern of four contact pairs illustrated in the embodiment of FIG. 3a, the overall diameter of the connector housing may be about 10-15% larger than the overall diameter of the pattern incorporating four contact pairs illustrated in FIG. 2a. However, the spatially optimum contact configuration illustrated in FIG. 2a yields poor crosstalk results, precluding use in applications that require stringent control of such interference. In rectangular configurations (FIGS. 3b and 3c) tessellation of the “T” pattern allows multiple Ethernet lines to be placed within a larger connector with relative spatial efficiency.

As the present invention provides a connector that may incorporate a traditional pin and socket design, the connector may be made using various methods of insulating and retaining the contacts within the connector housing known to those skilled in the art. One method of connector retention employs resilient plastic or metal spring clips to locate and retain the individual contacts. Each clip is designed to allow a contact to be inserted from one direction, and retain that contact once inserted to the proper depth. While this type of connector may be ideal for electrical applications where noise and signal cross-contamination need to be carefully controlled, retainer clip inserts have the drawback of being relatively difficult to seal hermetically, and are not particularly robust mechanically. Some designs may show susceptibility to vibration and there are applications where a tamper-resistant connector will be highly desirable. Therefore, while any method known to those skilled in the art may be employed for retention or insulation of the contacts in the connectors of the present invention, methods that will produce a ruggedized connector are employed in one embodiment. In one embodiment, the connector is hermetically sealed.

The electrical contacts may be insulated by encapsulating them within a molded insulation material. Encapsulation may be performed using techniques that will be understood by one of ordinary skill in the art from the description herein. This material could be rubber or a rigid plastic, e.g. thermoplastic, thermoset, etc. The contact may be completely and intimately surrounded by the dielectric to hermetically seal the contact. Some molded inserts, such as MIL-C-24231 receptacles, must be terminated prior to molding the insulator, while others, such as MIL-C-24231 plugs, can be terminated afterwards. In almost all instances of the latter case, multi-contact inserts must be solder-terminated. Because of the nature of the molding processes involved, the dielectric insulation may be a solid material.

Molded inserts are mechanically robust because they are composed of a uniform piece of material and are not susceptible to damage which may occur when contacts are inserted. They are also easier to seal hermetically because many materials can be bonded to metal contacts and a smooth outside surface condition is easier to achieve for elastomeric seals. Molded connectors are tamper-resistant, mechanically robust, and the insulation material can be chosen to suit any particular thermal or chemical environment. They also are relatively inexpensive in large volumes because the molding process can be automated.

The connectors may also be glass to metal seal connectors according to one embodiment of the present invention. Glass to metal seal connectors are currently the style of choice when end users require a connector that will be put into a harsh environment, e.g. oil & gas drilling, extreme underwater depths with submarines and ROV's, high altitude aircraft, nuclear reactors, etc., because the connectors are mechanically robust and can perform well in such harsh environments. In conditions of over 30,000 PSI of pressure or at temperatures in excess of 300° C., the connectors exhibit little to no degradation of performance. They achieve this by using metal housings typically of high grade materials, e.g. stainless steel 316L, K500 Monel, titanium alloy, etc. Glass preforms and electrical contacts are then loaded into the metal housings into differing configurations, and the assembly is then placed into a furnace at a temperature high enough to melt the glass around the contacts, but low enough to not melt or distort the contacts or the metal housings. If the glass and metal have substantially different coefficients of thermal expansion, the part is subjected to a specific cooling cycle after the glass is melted to form a compression seal. If the coefficients are substantially similar, the materials will form a matched seal upon cooling.

Glass to metal seals can come in various shapes, sizes, and styles. The glass used can be configured in many different ways to achieve particular design objectives. There are low temperature glasses that will melt at lower temperatures, which can be useful if the final assembly requires multiple glass seal steps. A high temperature glass can then be glass sealed into a larger assembly using a lower temperature glass. Low temperature glass can also be useful if the metals being used have lower melting points or annealing temperatures. The glass can be drawn and cut to size, sintered from glass powder, or cast from a molten state. The glass is the insulation dielectric in a glass to metal seal, and will typically have a dielectric constant between 5 and 6.

Embodiments of the invention that incorporate a conductor pair or connector contact pair pattern, such as illustrated in FIG. 1a, 1b, or 1c, provide a differential mode signal connector and cable assembly that may be used for high speed signal transmission while preventing crosstalk. Aspects of the present invention provide the advantage of limiting the occurrence of crosstalk in circumstances caused by imperfections in the geometry as allowed by positional tolerances and imperfections intrinsic to the method of contact termination, for example. Additionally, crosstalk results in such arrangements are independent of both contact spacing and dielectric insulation material.

Embodiments of the invention also include differential mode signal connectors and cable assemblies that may be adequately ruggedized for military and industrial applications that are easily manufactured, and are therefore a cost-effective alternative to present differential mode signal connectors and cable assemblies.

### EXAMPLE

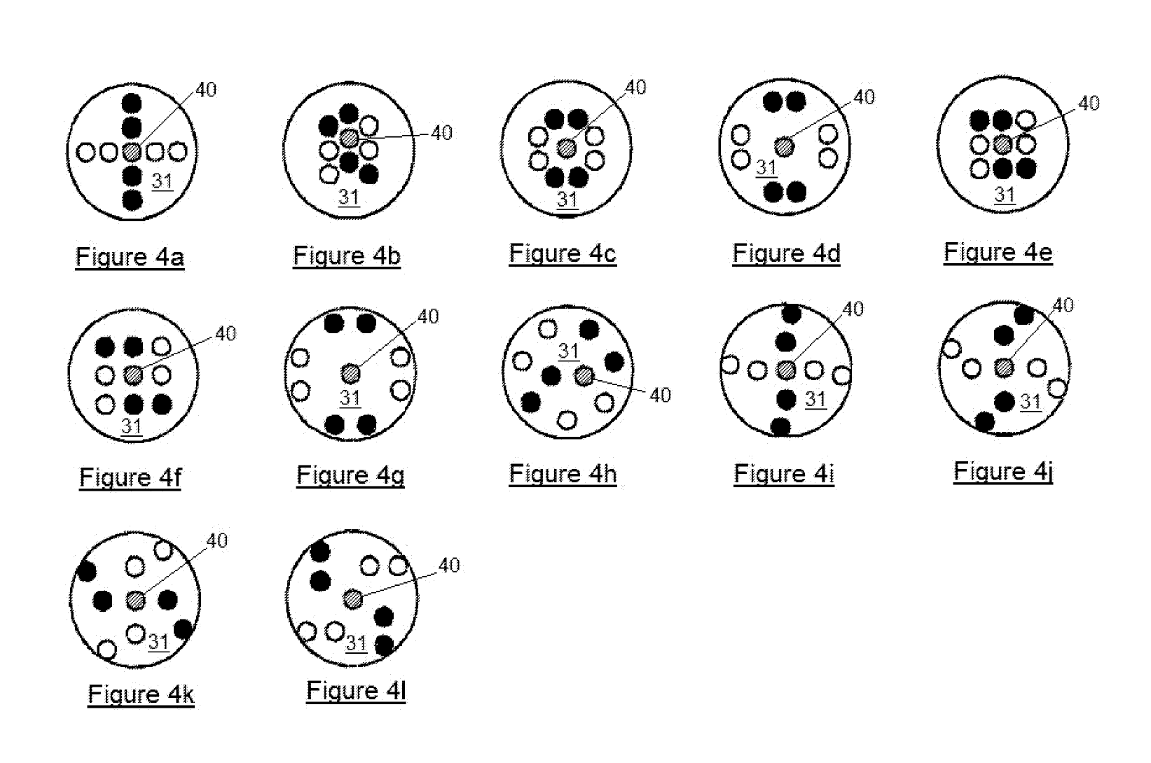

The present invention may be best understood in view of the following non-limiting example. Using like materials (the same dielectric insulation material, pin contacts, socket contacts, and cable were employed), and varying only the contact pattern geometry, various different contact arrangements, as shown in FIGS. 4a through 4l, were subjected to comparative performance testing for potential use in circular Ethernet connectors. A ninth pin 40 was present for this application, which was intended for use in shield termination. The crosstalk exhibited by each configuration was measured and the difference between the measured value and the allowable Category 6 limit for crosstalk was calculated. The results presented as a margin for Near-End Crosstalk (NEXT) are provided below in Table 1.

TABLE 1
Category 6 NEXT Performance in Various Configurations

| Configuration (Figure) | PASS/FAIL | NEXT Margin (dB) |
|---|---|---|
| 4a | PASS | 5.0 |
| 4b | FAIL | (1.0) |
| 4c | PASS | 0.6 |
| 4d | PASS | 4.3 |
| 4e | FAIL | (3.0) |
| 4f | FAIL | (0.6) |
| 4g | PASS | 2.6 |
| 4h | PASS | 0.7 |
| 4i | PASS | 8.5 |
| 4j | PASS | 11.5 |
| 4k | PASS | 12.8 |
| 4l | PASS | 14.2 |

As shown in Table 1, spatially optimized contact configurations fared much worse than those which spread the contact pairs a greater distance, but ultimately the configuration which performed the best were the contact configurations according to the present invention in FIGS. 4k and 4l. The configuration patterns as shown in FIG. 4l was re-tested using different contact spacing, contact lengths, and dielectric insulation materials, all of which were shown to have no appreciable impact on crosstalk.

This “T” pattern geometry incorporated into the various designs of the present invention has implications wherever differential mode communications are used in cables and traditional pin and socket contact connectors. For Ethernet applications, which are perhaps the most common use of such communications, this technology places Category 6 performance within easy reach of traditional connector designs. Traditional pin and socket connectors are much more robust and reliable than RJ connectors; therefore, the present invention which incorporates pin and socket connectors may be easily ruggedized for military or industrial applications. Despite the need to provide additional space to accommodate the optimal contact pattern for the connector assembly of the present invention, the present invention provides a connector design having a more efficient use of space than encapsulated RJ designs. Further, this technology provides a clear set of design guidelines for arranging contacts and conductors for multiple differential mode communication lines, whether used by themselves, or in combination with other elements within the same connector package. Lastly, by reducing crosstalk, higher transmission frequencies will be made available for RS-422, Ethernet, and other differential signal data transmission protocols, which may in turn lead to the development of less expensive, more robust, and higher bandwidth extensions of these protocols.

While preferred embodiments of the invention have been shown and described herein, it will be understood that such embodiments are provided by way of example only. Numerous variations, changes, and substitutions will occur to those skilled in the art without departing from the spirit of the invention. Accordingly, it is intended that the appended claims cover all such variations as fall within the spirit and scope of the invention.

What is claimed is:

1. A cable assembly comprising:
a cable having two opposing ends; and
a plurality of conductor pairs extending through said cable, each conductor in a first conductor pair being equidistant to each conductor in a second conductor pair.

2. The cable assembly of claim 1, further comprising:
a connector attached to one of said two opposing ends of said cable; and
a plurality of connector contact pairs extending through said connector, each connector contact being associated with one of said conductors and each connector contact in a first connector contact pair being equidistant to each connector contact in a second connector contact pair.

3. The cable assembly of claim 2, wherein the first conductor pair is adjacent to the second conductor pair.

4. The cable assembly of claim 2, wherein the first connector contact pair is adjacent to the second connector contact pair.

5. The cable assembly of claim 2, wherein said connector contacts are insert molded in said connector.

6. The cable assembly of claim 2, wherein said connector comprises glass or ceramic encapsulating at least one of said connector contacts.

7. The cable assembly of claim 2, wherein said connector is a hermetically sealed connector.

8. The cable assembly of claim 2, wherein said plurality of connector contact pairs is an odd number.

9. A connector assembly comprising:
a housing; and
a plurality of connector contact pairs extending through said housing, said plurality being an odd number and each connector contact in a first connector contact pair being equidistant to each connector contact in a second connector contact pair.

10. The connector assembly of claim 9, wherein the first connector contact pair is adjacent to the second connector contact pair.

11. The connector assembly of claim 9, wherein said connector contacts are insert molded in said housing.

12. The connector assembly of claim 9 further comprising glass or ceramic encapsulating at least one of said connector contacts.

13. The connector assembly of claim 9, wherein the connector assembly is a hermetically sealed connector.

14. A connector assembly comprising:
a housing; and
a plurality of insert molded connector contact pairs extending through said housing, each connector contact in a first connector contact pair being equidistant to each connector contact in a second connector contact pair.

15. The connector assembly of claim 14, wherein the first connector contact pair is adjacent to the second connector contact pair.

16. A connector assembly comprising:
a housing; and
a plurality of hermetically sealed connector contact pairs extending through said housing, each connector contact in a first connector contact pair being equidistant to each connector contact in a second connector contact pair.

17. The connector assembly of claim 16, wherein the first connector contact pair is adjacent to the second connector contact pair.

18. The connector assembly of claim 16, further comprising glass or ceramic encapsulating at least one of said connector contacts.

19. A layered circuit board comprising:
a first pair of conductors extending through a first plane; and
a second pair of conductors extending in the same direction as the first pair of conductors on a second plane that is perpendicular to the first plane, the conductors in the first and second pair of conductors are parallel to each other, and each conductor in the first pair of conductors being equidistant to each conductor in the second pair of conductors.

20. The layered circuit board of claim 19, wherein the first pair of conductors is adjacent to the second pair of conductors.
